(19) United States
(12) Patent Application Publication
(10) Pub. No.: US 2023/0107442 A1
(43) Pub. Date: Apr. 6, 2023

(54) PROCESSING 1H-NMR SPECTRAL DATA

(71) Applicant: Imperial College Innovations Limited, London (GB)

(72) Inventors: Panteleimon G. TAKIS, London (GB); Matthew R. LEWIS, London (GB)

(73) Assignee: Imperial College Innovations Limited, London (GB)

(21) Appl. No.: 17/922,678

(22) PCT Filed: Dec. 15, 2020
(86) PCT No.: PCT/GB2020/053215

§ 371 Date: Nov. 1, 2022

(30) Foreign Application Priority Data
May 1, 2020 (GB) 2006494.5

(51) Int. Cl. G01R 33/46

(52) U.S. Cl. CPC G01R 33/4625

(57) ABSTRACT

A computer-implemented method of processing ¹H-NMR spectral data is disclosed. The method comprises receiving ¹H-NMR spectral data for a sample or set of samples, performing a Fourier transform of the ¹H-NMR spectral data to obtain Fourier-transformed spectral data, first differentiating the imaginary part of the Fourier-transformed spectral data or processed Fourier-transformed spectral data obtained from the Fourier-transformed spectral data to obtain a first derivative and storing the first derivative in storage.

### FIELD

The present invention relates to processing ¹H-NMR spectral data.

### BACKGROUND

¹H (or proton)-Nuclear Magnetic Resonance (NMR) spectroscopy is a well-established technique used throughout clinical, population-scale, pharmaceutical and agricultural product research for qualitative and quantitative analyses of small molecules (SMs) in complex samples. It is also increasingly used to measure the abundance of larger structures such as lipoprotein species in blood plasma and serum and indirectly estimate NMR-invisible components of biofluids. All these types of measurements are captured in the single most common experiment in metabolomics and clinical research applications, the ¹H-NMR one-dimensional general profile experiment with solvent signal suppression (e.g., one dimensional nuclear Overhauser effect spectroscopy, 1DNOESY pulse sequence). However, broad baseline signals arising from macromolecular content (e.g., proteins and lipids abundant in serum/plasma, urine from subjects with pathological conditions, cerebrospinal fluid, saliva, tissues, cell lysates, pancreatic fluid, and food matrices such as milk, oil etc.) can overlap with and even hide the SM signals in a spectrum, inhibiting the efficiency of their deconvolution for annotation and quantification. More importantly, variability in macromolecule concentrations among samples results in baseline fluctuations which hinder the robust determination of SM contribution to diagnostic phenotypic signatures and/or fingerprinting by multivariate analysis (MVA).

These issues may be addressed by physically removing the macromolecules, for example, by ultra-centrifugation with filtering, but the time and cost required for sample processing, potential for introducing procedural variability, and negative impact to the integrity of the sample itself all undermine the key strengths of NMR as a high-throughput, intrinsically precise and non-destructive technique. Instead, the more practical and routinely applied approach is to suppress resonances from macromolecular-derived signals on instrument. This is accomplished by performing an ancillary “spin-echo” experiment such as the Carr-Purcell-Meiboom-Gill (CPMG) pulse sequence which filters macromolecular signals via transverse relaxation times (T₂), generating a 1D spectrum of slow relaxing signals, mainly belonging to SMs. The approach is sufficiently reproducible although imperfect in its suppression of broad resonances given the time limit for large cohort studies (e.g., metabolomics) and unsuitable for direct absolute quantification, as the signal integral is modulated by the high variability of T₂ values for each proton spin system from each SM. It is also time consuming, contributing substantially to the acquisition time required by standard profiling workflows. The approach is therefore costly, especially at the scale required for the routine analysis of samples from epidemiology cohorts, food industry quality control, and other large-scale applications.

### SUMMARY

According to a first aspect of the present invention there is provided a computer-implemented method of processing ¹H-NMR spectral data. The method comprises receiving ¹H-NMR spectral data for a sample, performing a Fourier transform of the ¹H-NMR spectral data to obtain Fourier-transformed spectral data, first differentiating the imaginary part of the Fourier-transformed spectral data or processed Fourier-transformed spectral data obtained from the Fourier-transformed spectral data to obtain a first derivative, and storing the first derivative in storage.

This process can be used to obtain an NMR spectrum or set of spectra in which signals from small molecules in the sample are enhanced by suppressing baseline confounding broad ¹H-NMR signals arising from macromolecules (such as, for example, proteins, lipids and/or polysaccharides).

The method may comprise processing ¹H-NMR spectral data for a set of samples, each ¹H-NMR spectral data provided for a respective sample.

The ¹H-NMR spectral data (or “¹H-NMR spectrum”) may take the form of a free induction decay or other time-dependent signal (or “time-domain signal”). The ¹H-NMR spectral data may be expressed in terms of relative intensity as a function of time.

The Fourier-transformed spectral data is a frequency-dependent signal (or “frequency-domain signal”) and may be expressed in terms of amplitude as a function of chemical shift (usually in units of ppm). The first derivative is a frequency-dependent signal.

The imaginary part of the Fourier-transformed spectral data or processed Fourier-transformed spectral data may comprise a set of datapoints and first differentiating the imaginary part of the Fourier-transformed spectral data or processed Fourier-transformed spectral data may comprise, at each of said datapoints, determining a value of a first derivative of the imaginary part of the Fourier-transformed spectral data or processed Fourier-transformed spectral data.

First differentiating the imaginary part of the Fourier-transformed spectral data or the processed Fourier-transformed spectral data may also be referred to as “taking the first derivative of the imaginary part of the Fourier-transformed spectral data or the processed Fourier-transformed spectral data”.

Performing the Fourier transform may comprise performing a one-dimensional Fourier transform of the ¹H-NMR spectral data. Performing the Fourier transform may comprise performing a numerical Fourier transform of the ¹H-NMR spectral data.

The ¹H-NMR spectral data may comprise or consist at least 65,000 (or 2¹⁶) datapoints.

The Fourier-transformed spectral data may have a spectra width of up to 20 ppm.

The method may further comprise apodizing (or “windowing”) the ¹H-NMR spectral data prior to performing the Fourier transform using an apodization function. This can help improve signal-to-noise.

The apodization function may be, for example, an exponential multiplication, Gaussian multiplication or other suitable function for enhancing signal-to-noise ratio. The exponential multiplication may take the form exp [-kt], where k is a line broadening factor and t is time. The Gaussian multiplication may take the form exp [-(kt)²], where k is a line broadening factor and t is time. The line broadening factor k may take a value between 0.1 and 1 Hz.

The method may further comprise processing the Fourier-transformed spectral data to generate processed Fourier-transformed spectral data.

Processing the Fourier-transformed spectral data may comprise performing phase correction on the Fourier-transformed spectral data. Performing phase correction may comprise multiplying the real part of the Fourier-transformed spectral data by sine function and the imaginary part of the Fourier-transformed spectral data by cosine function.

The method may further comprise denoising the first derivative. This can help improve signal-to-noise. Thus, the first derivative stored in storage is a denoised first derivative.

Denoising the first derivative may comprise applying a low-pass filter. The low-pass filter may have coefficients equal to the reciprocal of window span, i.e., the span of the first derivative.

Denoising the first derivative may comprise applying local regression. Applying the local regression may comprise applying local regression using weighted linear least squares and a first-degree polynomial model and/or applying local regression using weighted linear least squares and a second-degree polynomial model.

Denoising the first derivative may comprise applying a Savitzky-Golay filter. Applying a Savitzky-Golay filter generally involves a moving average with filter coefficients determined by an unweighted linear least-squares regression and a polynomial model of specified degree.

The method may further comprise displaying the first derivative (which may be de-noised). The method may comprise displaying a ¹H-NMR spectral plot for comparing with first derivative.

According to a second aspect of the present invention there is provided a computer program product comprising a non-transitory computer readable storing or carrying a computer program which comprises instructions which, when executed by at least one processor, causes the at least one processor to perform the method of the first aspect.

According to a third aspect of the present invention there is provided apparatus comprising at least one processor and memory, wherein the at least one processor is configured to receive ¹H-NMR spectral data for a sample, to perform a Fourier transform of the ¹H-NMR spectral data to obtain Fourier-transformed spectral data, to first differentiate the imaginary part of the Fourier-transformed spectral data or of processed Fourier-transformed spectral data obtained from the Fourier-transformed spectral data to obtain a first derivative and to store the first derivative in memory or storage.

According to a fourth aspect of the present invention there is provided a system comprising storage (for example, a hard-disk drive or solid-state drive) storing one or more sets of ¹H-

NMR spectral data, and apparatus for processing ¹H-NMR spectral data, the apparatus configured to retrieve the one or more sets of ¹H-NMR spectral data from storage and to perform the method of the first aspect on each respective set of ¹H-NMR spectral data.

According to a fifth aspect of the present invention there is provided a system comprising a ¹H-NMR measurement system for generating ¹H-NMR spectral data for a sample and apparatus for processing ¹H-NMR the spectral data, the apparatus configured to perform the method of the first aspect using ¹H-NMR spectral data from the ¹H-NMR measurement system.

### BRIEF DESCRIPTION OF THE DRAWINGS

Certain embodiments of the present invention will now be described, by way of example, with reference to the accompanying drawings, in which:

FIG. 1 illustrates Small Molecule Enhancement SpectroscopY (SMolESY) analytical reproducibility and performance in various matrices. (A) 1D-NOESY, CPMG and SMolESY spectra of Albumin titration (0-225 mM). Carr-Purcell-Meiboom-Gill (CPMG) spectra exhibit ineffective suppression of Albumin signals (light blue boxed areas, labelled BA), whereas SMolESY achieves their complete attenuation. Moreover, SMolESY maintains small molecules (herein impurities) fingerprint. 1D-NOESY, CPMG and SMolESY spectra of (B) bovine milk and (C) olive oil, focused on the fatty acids-lipids aliphatic groups ¹H-NMR region. It is clearly shown that SMolESY supersedes the routine CPMG spectrum, enhancing the resolution by effectively narrowing the broad NMR signals of the aliphatic chains and increasing resolution. In addition, SMolESY affords the direct quantification by integration of several SMs, which are easily detected/assigned compared to both 1D-NOESY and CPMG spectra, where spectral deconvolution is needed. (D) Integrals of five 1D-NOESY ¹H-NMR signals from cytidine in the artificial mixture of metabolites in 9 concentrations were correlated with the SMolESY with a linear correlation (R² > 0.985), passing through the origin (dashed circle), and the statistical one-way ANOVA tests confirmed all intercepts/slopes coincidence (horizontal/vertical error bars show ± 1% integration error). Regardless of signals multiplicity (doublets with different j-coupling, multiplets, triplet), SMolESY shows intra-metabolites analytical reproducibility. (E-H) PCA of a urine dataset produces the same results for both 1D-NOESY and SMolESY, capturing similar cumulative variability, whereas loading plots point at the same variables for groups discrimination.

FIG. 2 illustrates SMolESY performance in more than 2000 plasma-heparin samples. (A-O) Mean spectrum of 2026 plasma-heparin 1D-NOESY (upper panel), CPMG (middle panel) and SMolESY (bottom panel) spectra zoomed at ~0.5 ppm window from 0.55-8.7 ppm. The mean SMolESY spectrum is colored according to the Pearson coefficients from SMolESY versus CPMG signals correlation in 2026 spectra. The majority of highly resolved SMolESY signals are linearly correlated to the CPMG and > 99.5% of CPMG features of SMs are maintained, while successfully suppressing the broad signals of macromolecules in contrast to CPMG (examples of unsuppressed CPMG broad signals are highlighted by red dashed boxes). It is noted that broad signal of urea along with 3-4 broad signals of very low abundance (i.e. < 1.5 times the CPMG noise) metabolites are highly suppressed and exhibit low correlation to the CPMG (black dashed boxes in panel L), even though being recovered by the SMolESY.

FIG. 3 illustrates STOCSY analyses between SMolESY versus CPMG 994 plasma-EDTA spectra. (A) 1,5-anhydroglucitol, (B) Creatinine, (C) Citric acid, (D) L-threonine, (E) Ethanol, (F) L-proline, (G) L-alanine and (H) L-lactic acid metabolites assignment by STOCSY in the SMolESY(bottom panel) spectra outperforms CPMG (upper panel), indicating higher correlation values between all signals and maintaining metabolites NMR fingerprint. STOCSY in the SMolESY spectra shows correlations between all spin systems of L-threonine and L-proline (black dashed boxes) in contrast to CPMG. Moreover, STOCSY for L-alanine and ethanol, exhibits all expected correlations for both metabolites’ signals (i.e. one doublet and one quartet for L-alanine, one triplet and one quartet for ethanol), in contrary to the CPMG spectra which fail to map the spin systems multiplicity. Light blue circles indicate the corresponding spin systems of each metabolite. Chemical shift values of “driver” peaks (mentioned in the title of each panel) for the metabolites were taken from the mean spectrum of SMolESY spectra.

FIG. 4 illustrates SMolESY for binning and assignment-quantification. Comparison of SMolESY and CPMG spectral bins including signals of (A) L-phenylalanine, (B) L-aspartic acid and (C) ethanol spiked (11 concentrations) in a real plasma sample. Linear regression curves exhibit R² > 0.98, indicating high reproducibility of SMolESY, while superseding CPMG in broad signal suppression (error bars are omitted due to ~o error in bin integration). SMolESY signals (light blue circles - red lines, a pair of which are labelled for L acetone) from >20 plasma metabolites: (D) 2-hydroxybutyric acid, (E) Lisoleucine, (F) L-valine, (G) ethanol, (H) L-threonine, (I) L-lactic acid, (J) L-alanine, (K) acetic acid, (L) acetone, (M) citric acid, (N) N,N-dimethylglycine, (O) creatine, (P) creatinine, (Q) choline, (R) glycerol, (S) glycine, (T) L-tyrosine, (U) L-phenylalanine, (V) L-histidine, (W) ormic acid and many more metabolites (black dashed boxes) are completely deconvolved from the macromolecular content in contrary to the commonly employed for quantification 1D-NOESY spectrum and their direct integration could provide metabolites’ concentration values.

FIG. 5 illustrates SMolESY for absolute quantification. Absolute quantification was performed for 11 concentrations of several spiked metabolites: (A) acetone, (B) L-isoleucine, (C) L-glutamine, (D) citric acid, (E) L-valine, (F) lactic acid, (G) acetic acid, (H) L-threonine, (I) formic acid, (J) ethanol, (K) glycerol and (L) L-phenylalanine in a plasma matrix by SMolESY (i.e. by direct integration of the transformed signals of each metabolite) and 1D-NOESY by deconvolution/fitting algorithms (herein by the commercially available IVDr platform from Bruker Biospin) and plotted against the spiked concentration values. Linear regression analyses clearly show the ability of SMolESY for absolute quantification (R₂ > 0.97), and all calculated concentrations based upon SMolESY data are in reasonable agreement with the deconvolution results. It should be noted that no calibration was applied to the SMolESY integrals so as to account for e.g. T₁ relaxation times differences between ¹H spin systems from different chemical groups etc., whereas these refinements are implemented into the IVDr platform of Bruker Biospin. Hence, some slight discrepancies can be observed between SMolESY and the Bi-QUANT-PSTM values due to this refinement. The calculation of absolute concentration values is based upon the ERETIC signal (and its transformation) produced during the acquisition of 1D-NOESY data by Bruker. It is noteworthy that the instant quantification via integration has no computational cost and the deconvolution/fitting algorithms are prone to higher errors (see vertical error bars) compared to the integration process (± ~1%) of the already deconvoluted signals in “clean” baseline of SMolESY spectra. For the IVDr data, plotted error bars are taken from the Δ values produced by the corresponding reports.

FIG. 6 illustrates examples of enhanced spectral resolution by the imaginary NMR spectral part differentiation. (A) The real spectral data (i.e. doublet, d) of the spin system from the —CH₃ group of L-alanine in a typical plasma/serum matrix (upper panel). The 1st numerical derivative of the real data from the L-alanine —CH₃ ¹H-NMR signal (after Fourier transform and phase correction) (bottom panel), produces an antisymmetric signal (positive on one side and negative on the other). (B) The imaginary spectral data of the spin system from the —CH₃ group of L-alanine in a typical plasma/serum matrix (upper panel). In contrary to the real data, the 1st derivative of the imaginary data, due to its gradient (namely positive-negative maxima per signal) (bottom panel), produces a positive transformed signal. (C) Overlaid real and 1st derivative of the imaginary part of the L-alanine —CH₃ doublet spectral regions, show no chemical shifting, without the need of applying any symmetrisation algorithms. The transformed signal from the imaginary spectral data could be immediately employed for any NMR-based metabolomics or analytical study. (D) Comparison between the 2nd derivative of the real data of the NMR spectrum multiplied by -1 (this could be the same for the 2nd power derivative) and the 1st derivative of the imaginary part of the same spectral region, taken from a ¹H-NMR plasma spectrum. It is immediately appreciated that the signal-to-noise ratio of the 2nd derivative of the real spectral data is decreased compared to the 1st derivative of the imaginary part.

FIG. 7 is a schematic block diagram of an ¹H-NMR measurement system and an ¹H-NMR spectrum processing system.

FIG. 8 is a schematic block diagram of a computer system used in the ¹H-NMR spectrum processing system shown in FIG. 7.

FIG. 9 is a flow diagram of a method of processing a ¹H-NMR spectrum.

FIG. 10 illustrates SMolESY (upper panel), noise filtered SMolESY (middle panel) and the CPMG (lower panel) spectral regions, focusing on the ¹H-NMR signal of the proton from Formic acid (at ~0.02 mM) in a plasma sample. The selected singlet resonates in usually noisy spectral region of a plasma ¹H-NMR profile, consequently a quite large s/n decrease is expected after its transformation from the normal 1D ¹H-NMR (e.g. 1D NOESY) spectrum. Indeed, SMolESY spectrum shows the lowest s/n (~27% decrease compared to CPMG), whereas the application of a simple lowpass filter (i.e. filter coefficients equal to the reciprocal of the window span) results in ~18% increase of s/n compared to pure SMolESY signal, and exhibits quite similar s/n with CPMG (~10% lower than CPMG).

FIG. 11 illustrate a user interface for the SMolESY_platfrom. A) The development of SMolESY_platfrom provides the opportunity for any user to load 1D-NMR raw spectra, so as to transform them into SMolESY and export them into a .txt file. In addition, the user has the opportunity to calibrate the SMolESY spectra to the doublet of the anomeric proton of glucose (~5.25 ppm) in case of plasma/serum/CSF etc. acquired spectra. (B) It offers the possibility to plot both 1D ¹H-NMR and SMolESY spectra for a synchronized zoom in both panels, (C) as well as to align into specific reference peaks a set of spectral bins or individual signals so as to integrate SMolESY features either for qualitative (i.e. option of variable-size SMolESY spectra binning) or quantitative purposes (i.e. option of SMolESY signals integration for quantification). The alignment of the signals could be performed both manually or in a semi-automated way upon users experience and request. More details and user guidelines of the software could be found at: https://github.com/pantakis/SMolESY_platform, which is incorporated herein by reference.

### DETAILED DESCRIPTION OF CERTAIN EMBODIMENTS

### Introduction

A computer-implemented method of (or “approach to”) processing ₁H-NMR spectra, herein referred to as “SMolESY” (Small Molecule Enhancement SpectroscopY), is described. According to the SMolESY process, a first derivative of the imaginary part Fourier-transformed ¹H-NMR is obtained. The first derivative is herein referred to as SMolESY data or simply SMolESY. The SMolESY process can reliably increase resolution and deplete macromolecular signals directly from the ¹H ₁D-NMR spectrum with no intensity modulation. The approach relies on mathematical differentiation. By calculating the first partial derivative of the imaginary data of the NMR spectrum, SMolESY yields a profile of small molecules (SMs) free from large molecule signal baseline interference and sample-to-sample fluctuation. As the approach does not rely on T₂ or j-coupling constant modulation, the inherent quantitative quality of the conventional ₁H-NMR spectrum is preserved. Furthermore, the resolution of SMs derived signals is enhanced by as much as three-fold, enabling the annotation of otherwise overlapping signals and further facilitating their quantification. However, it is also commonly understood that derivatives are prone to instability when applied to signals of very low intensity, and therefore the practical effects of a reduced signal-to-noise ratio (s/n) required evaluation. Herein, we demonstrate that despite the lower s/n, for the case of SMs of biologically relevant complex mixtures, the signal’s limit of detection (LOD) is not functionally affected. To our knowledge, the application of our approach (even in its simplest form of differentiation without combined with any traditional or modern signal denoising filters) to biofluids or complex matrices of large cohort studies, with the view to suppressing signals of macromolecules across entire spectra in a systematic way, has never been reported or tested. Based upon our findings, the SMolESY approach may be used to functionally replace and additionally improve upon several weaknesses of traditionally used spin-echo experiments, particularly in the NMR-based metabolomics field. Before describing a system for processing ₁H-NMR data, experiments will be described which may be useful for understanding SMolESY approach.

The approach was applied to ¹H-NMR ₁D-NOESY spectra from various datasets of varying sample matrix complexity in order to systematically evaluate SMolESY performance.

### SMolESY Performance for Macromolecular Spectral Background Attenuation

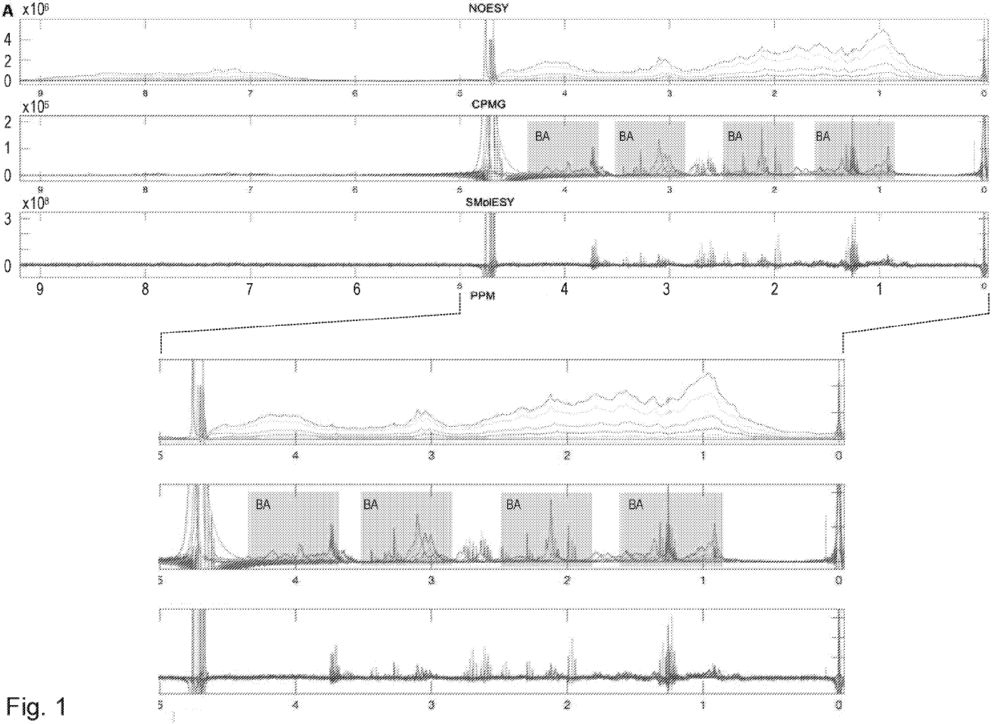

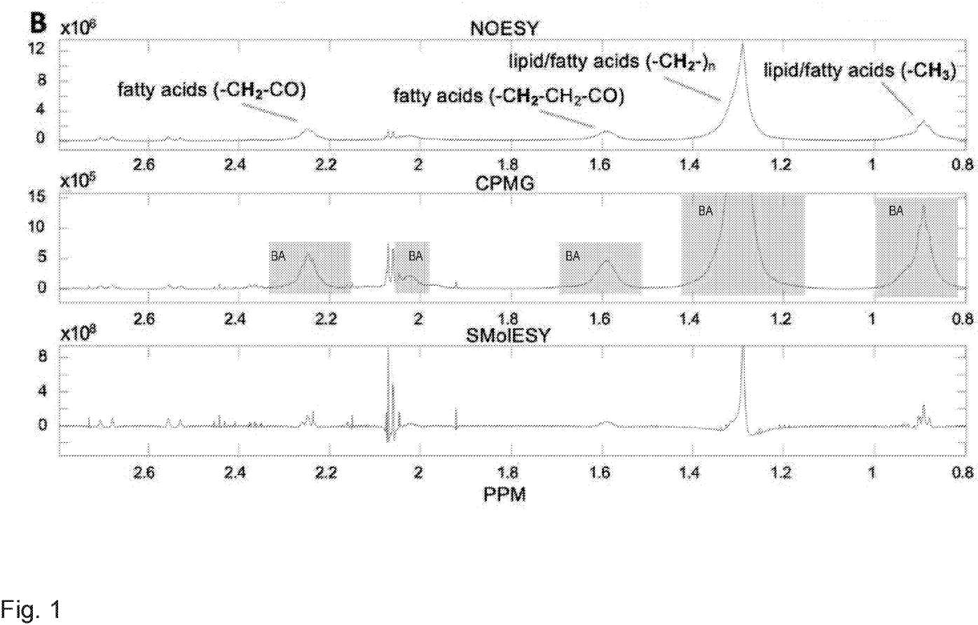

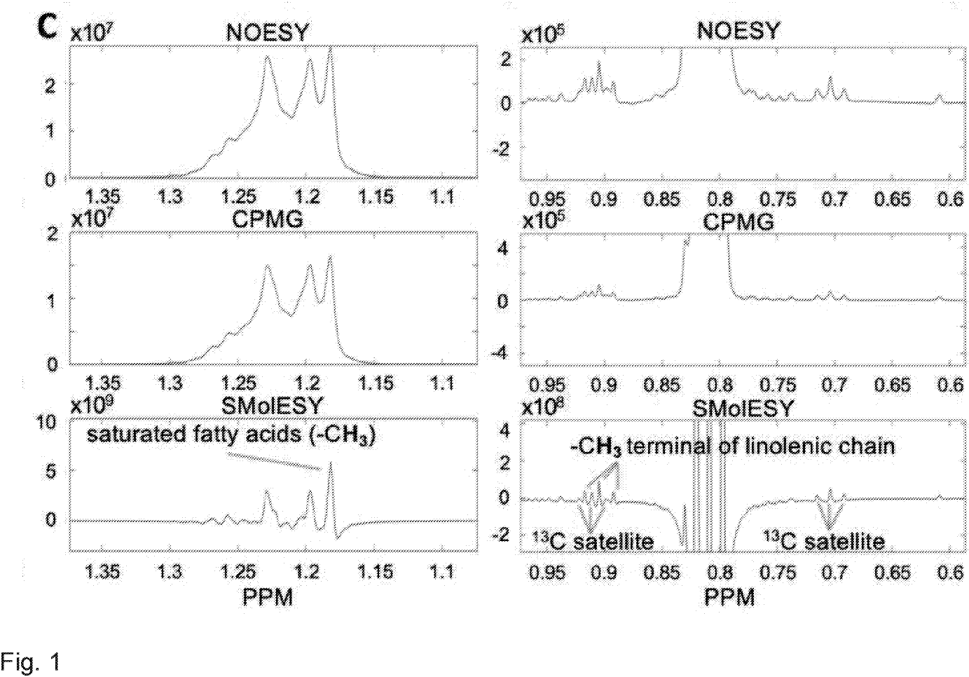

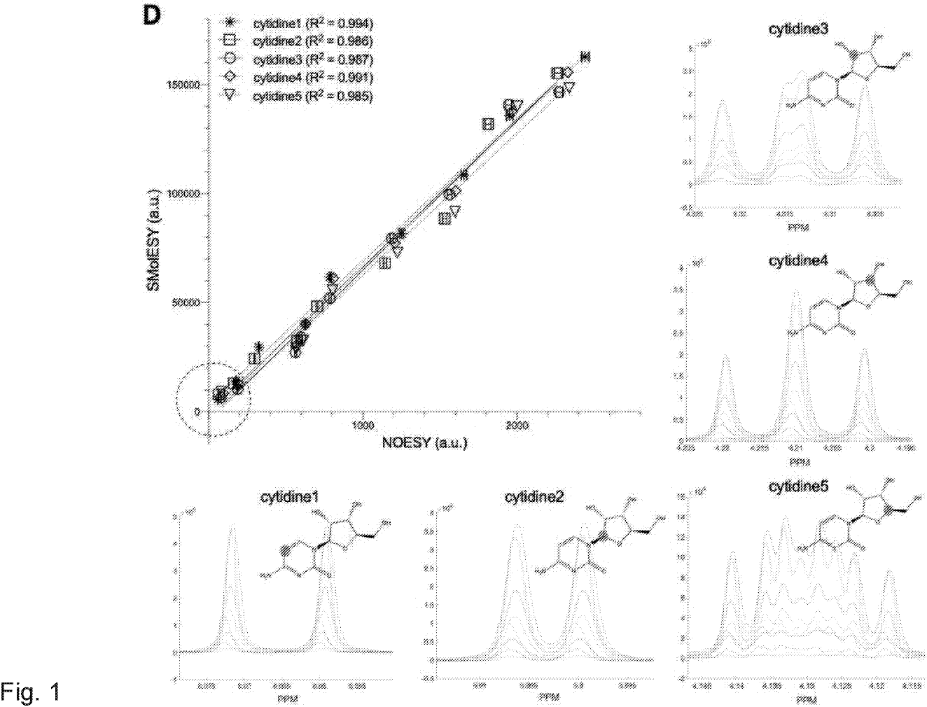

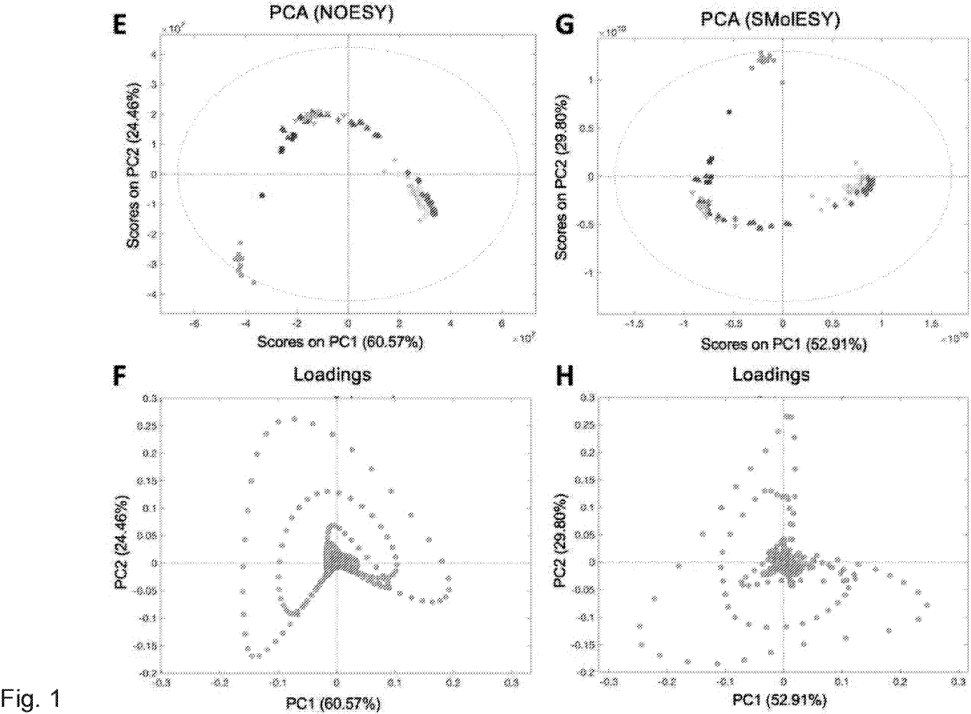

FIG. 1 illustrates Small Molecule Enhancement SpectroscopY (SMolESY) analytical reproducibility and performance in various matrices.

The first set of ₁D-NOESY and CPMG spectra were generated from a series of pure human serum albumin solutions at concentrations designed to span and exceed those found in normal human blood (FIG. 1A) and from two food matrices, namely of bovine milk and olive oil, respectively (FIGS. 1B,C). In all cases, the corresponding SMolESY spectra showed complete attenuation of large molecule derived broad signals resulting in zero-baselines across the whole spectral area. In the model albumin solutions SMolESY signals from SMs which belong to impurities embedded in the protein reagent appeared highlighted as they are the only observable resonance on the reprocessed spectra (FIG. 1A). For the milk solution, the commonly applied CPMG experiment in the NMR-based metabolomics pipeline resulted in unsuppressed ¹H-NMR broad signals of fatty acid chains (FIG. 1B), whereas SMolESY provided an effective broad signals attenuation. Furthermore, many resonating signals of milk metabolites7 on the edges of broad signals were sufficiently enhanced by SMolESY, so as to be easily assigned and quantified, which was not the case from their corresponding CPMG spectrum. The same effect was observed for the methyl group signal of olive oil saturated fatty acids which is utterly deconvolved from other methyl groups, as well as for the triplet of the methyl terminal group of linolenic acid which is easily separated by the ₁₃C satellites of other protons (FIG. 1C).

Validation of SMolESY signal integrity and intra-metabolite reproducibility: application to free and very low macromolecular content matrices. The second dataset was generated from synthetic mixtures of metabolites in varying concentrations (hereinafter described in the section Artificial mixtures preparation in Materials and Methods) designed to enable assessment of SMolESY fidelity across a comprehensive set of ₁H-NMR peak shapes and multiplicities (e.g. triplet, quartet etc.). The relationship between ₁D-NOESY and SMolESY peak integrals (FIG. 1D) was strongly linear with coefficient of determination (R²) values > 0.98 and passing through the origin regardless of signal multiplicity. This is demonstrated by evaluation of the uniquely shaped ¹H-NMR signals for 5 different ¹H spin systems present in cytidine (FIG. 1D) and further signals from other 6 SM. In addition, one-way ANOVA tests for the curves of different spin systems from the same metabolite proved that both slopes and intercepts coincide, indicating preservation of the ₁D-NOESY qualitative signal response in the SMolESY spectra. SMolESY was then applied on a third dataset consisting of publicly available ₁D-NOESY spectra from normal human urine samples (hereinafter described in Plasma - Urine spectra employed for the present study in the Experimental section). Urine’s complex SM composition in the virtual absence of macromolecules was used to assess SMolESY’s preservation of SM signal information. Principal Component Analysis (PCA) on both the ₁D-NOESY and SMolESY urine spectral datasets produced score plots with the same pattern of sample groups with similar cumulative captured variability (85% and 82.7% respectively) and loading plots with the same pattern of variable weightings (FIGS. 1E-H). The result demonstrates that the multivariate information sets recovered from each spectral type are equivalent, providing support for SMolESY’s use in classical metabolomics (pursuit of diagnostic and prognostic chemical patterns) and “fingerprinting” applications. Beyond the intended validation, the use case itself is of potential value as numerous pathological conditions can significantly increase urinary excretion of macromolecules such as albumin and lipids. Although metabolically interesting in their own right, the presence of such lipid/protein signals in urine samples can also confound any subsequent SM multivariate analyses and quantitation, since these signals would not be attenuated by NMR experiments routinely applied to urine samples or by preprocessing methods, for example, normalization. SMolESY therefore has an ability to salvage otherwise compromised spectra from specimen in sample sets where macromolecules would not be expected or planned for.

### Application of SMolESY Into Large Plasma Cohorts

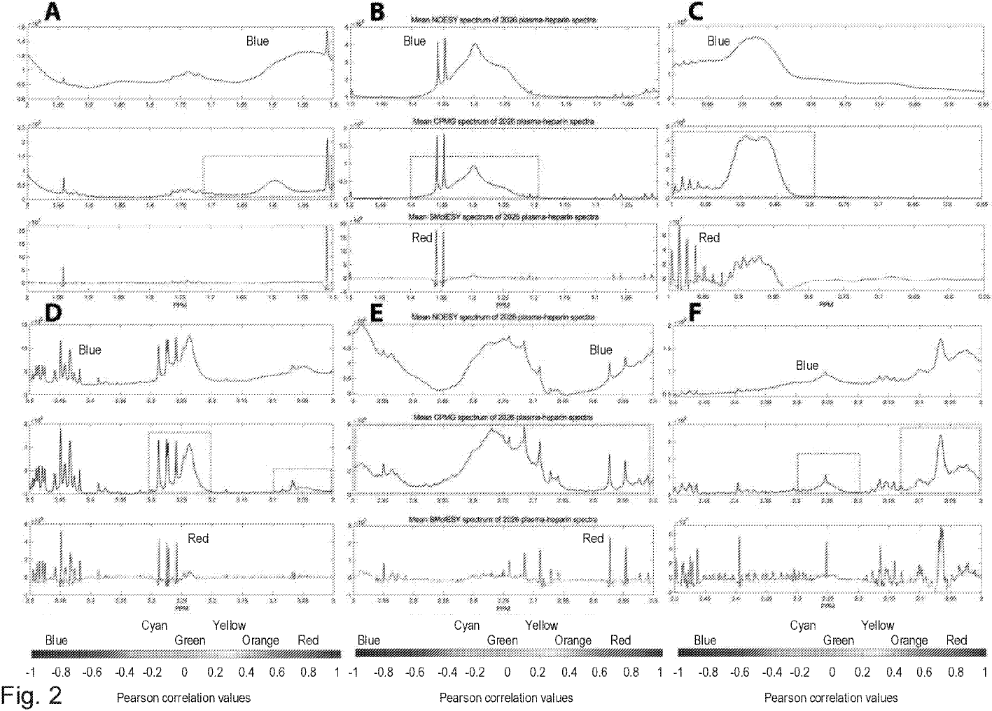

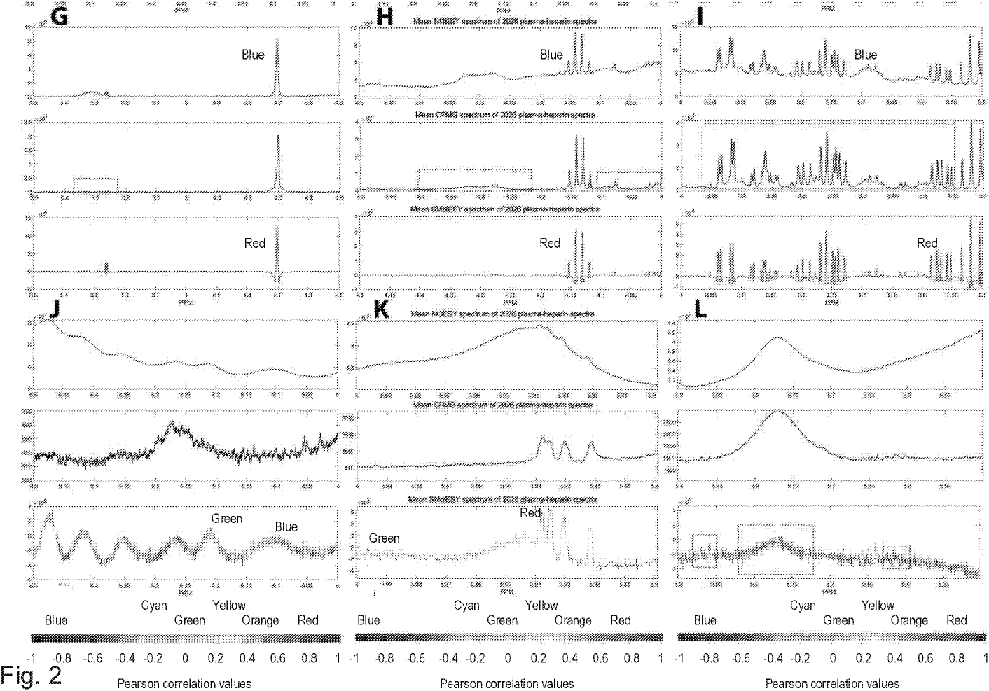

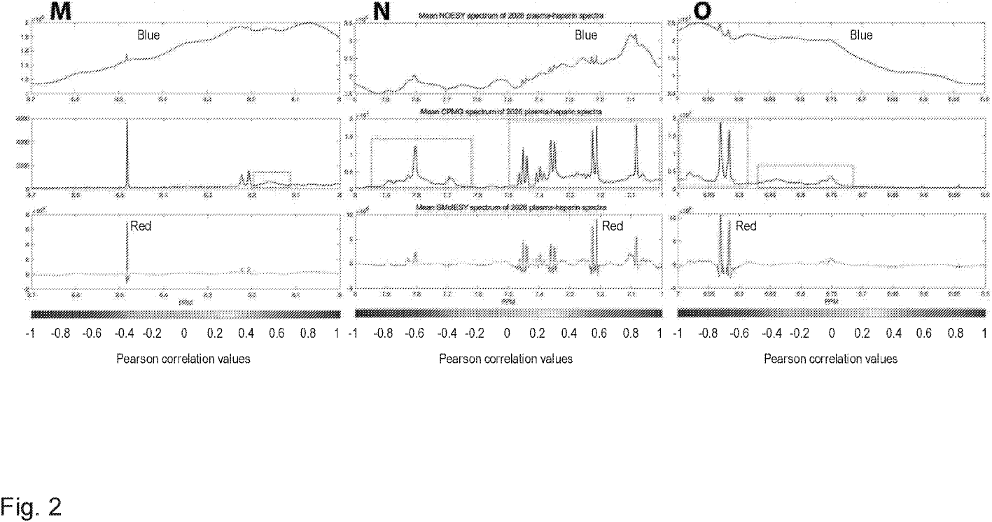

For the third dataset, SMolESY spectra were produced from a collection of 3020 1D-NOESY profiles of human plasma samples from two different cohorts (2026 plasma-heparin and 994 plasma-EDTA samples) (hereinafter described in Plasma - Urine spectra employed for the present study in the Experimental section) so as to increase sample content variability and compared to their corresponding CPMG spectra. Pearson correlation between the SMolESY and CPMG spectra showed that 73% of transformed peaks were highly correlated with r > 0.90 (FIG. 2). The remaining 27% of peaks correspond to either CPMG peaks convolved with poorly suppressed broad signals (FIGS. 2A-I,N-O), those lying on the edges of signals from highly abundant metabolites, or those not visible in the CPMG because of significant peak overlap but resolved in the SMolESY spectra. Evaluation of the differentiation’s effect on spectral s/n in exemplar analytes revealed an average decrease of 30% in SMolESY versus CPMG spectra (hereinafter described in Experimental section “Signal-to-noise ratio (s/n) and peak picking calculations”). However, the net effect of SMolESY on retrievable small molecule information across the entire spectrum appeared positive, with a 34% increase in the number of detected signals over the CPMG. Together, these results confirm the inter-spectra reproducibility of SMolESY and its outperformance on the CPMG, since the total number of SMs SMolESY NMR visible features is higher than in the CPMG. Only four broad signals (representing less than 1% of the total transformed peaks) were less well represented in the SMolESY spectra than the CPMG (FIG. 2L). These signals corresponded to the broad linewidth to the half-height (Δv_{½}) of the urea NMR peak

$$\left(\text{CPMG} \overline{Δ \text{v} {}_{1 / 2}} ∼ 40 \text{Hz}\right) ,$$

such as urea, and very low abundance unknown metabolites (1.5 < signal-to-noise ratio < 2.2,

$$C P M G \left(\overline{Δ \text{v} {}_{1 / 2}} ∼ 10 \text{Hz}\right)$$

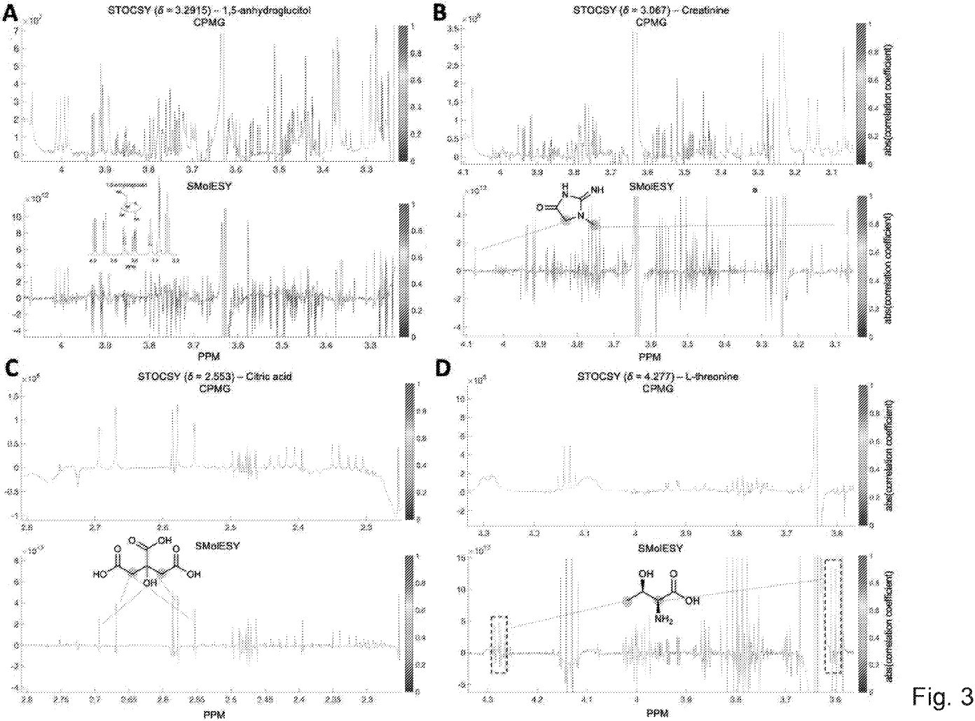

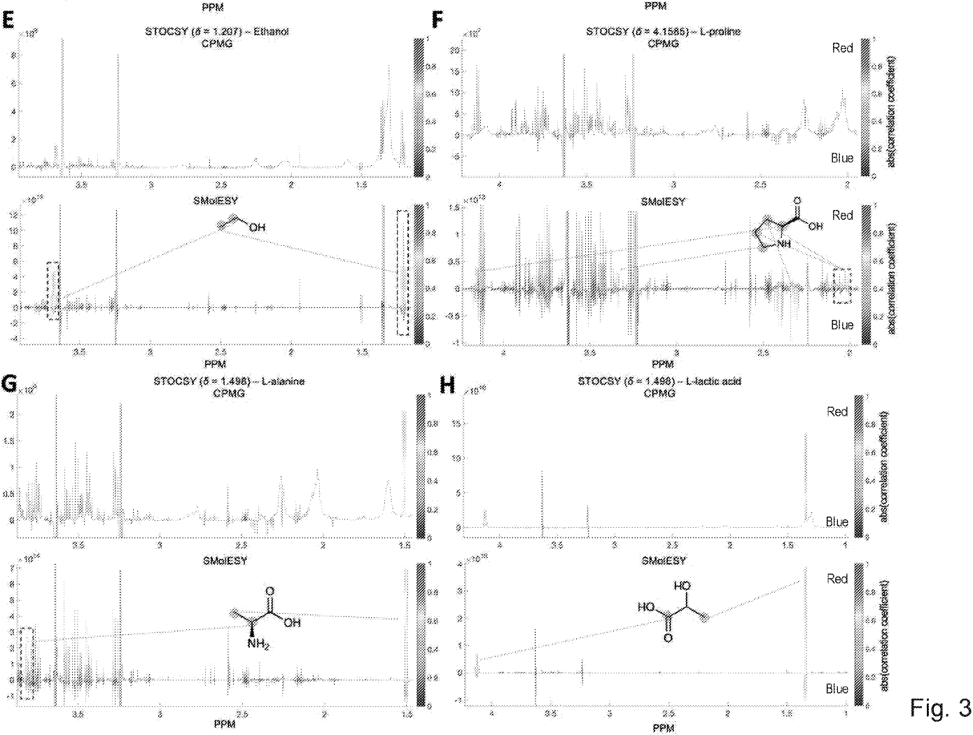

(FIG. 2L). It is well known that quantitation of any SM containing labile ¹H is compromised when water suppression techniques are used, hence the urea signal ends up being excluded from the MVA in the majority of studies. Ad-hoc experiments may be used in to accurately quantify these types of metabolites. Additionally, statistical correlation analyses by statistical total correlation spectroscopy (STOCSY) (FIG. 3) were applied to several low to high structural complexity molecules in the SMolESY plasma data, further confirming that correlation structure in the dataset is preserved and additionally demonstrating the potential for enhanced metabolite identification in SMolESY spectra arising from the improvement in signal resolution (FIG. 3). For instance, the signal multiplicities of several ¹H spin systems for L-threonine (FIG. 3D) and L-proline (FIG. 3F) were better resolved, leading not only to a better assignment of their signals but also to a substantial deconvolution of other SM signals in several spectral areas confounded by broad NMR signals of plasma lipoproteins. Both correlation and STOCSY results confirm the efficacy and fidelity of SMolESY, with more 1D-NOESY SM features maintained (> 99%) than those visible by CPMG owing to the resolution enhancement. It is noteworthy that the resolution enhancement of SM peaks due to Δv_{½} narrowing is further improved by the complete removal of broad signals background.

### SMolSEY Employment and Implementation to NMR-Based Metabolomics and Analytical Studies

There are two other characteristics for helping successful implementation of SMolESY to -omics and analytical studies are spectral binning and absolute quantification. These were addressed using NMR experiments where 17 common biological metabolites in various known concentrations were spiked-in to a real plasma matrix to provide a SM profile against a constant macromolecular background (described hereinafter in Artificial mixtures preparation-Spiking experiments in the Experimental section).

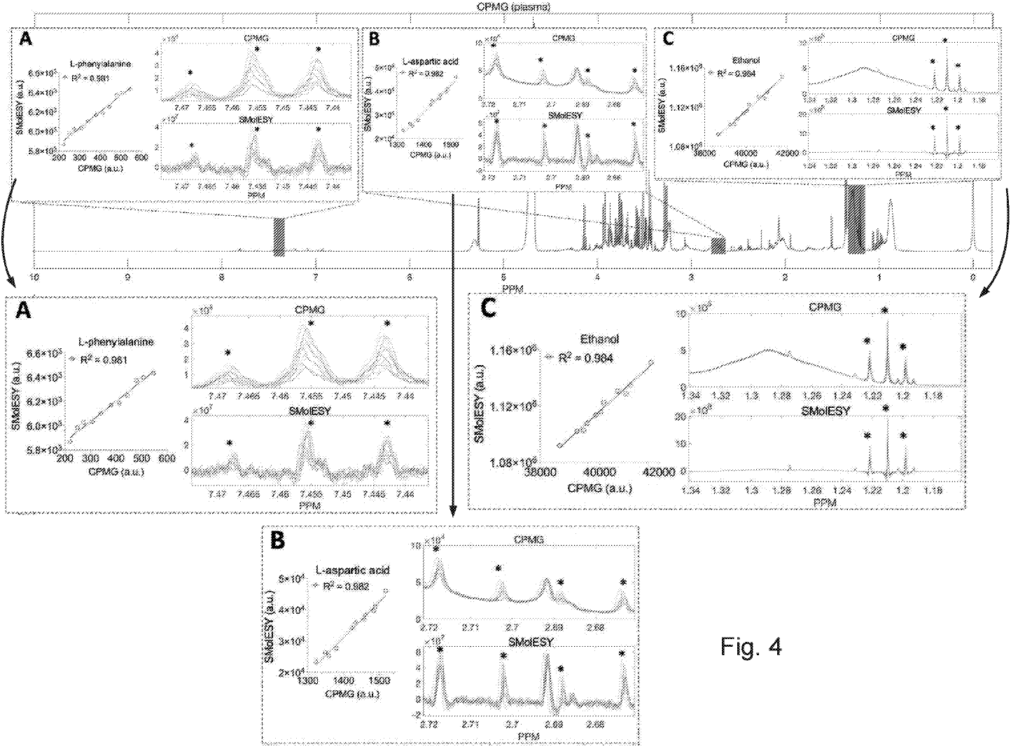

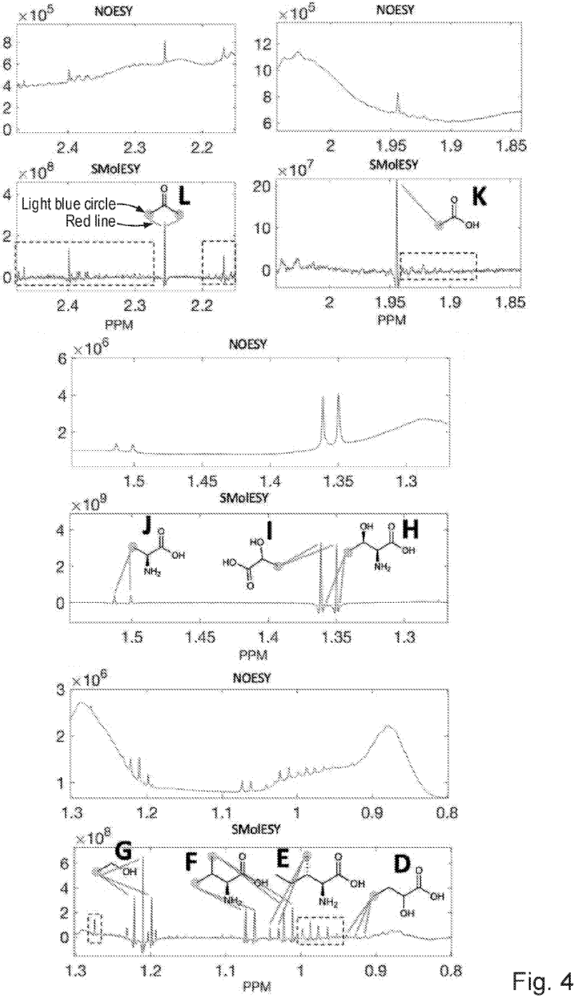

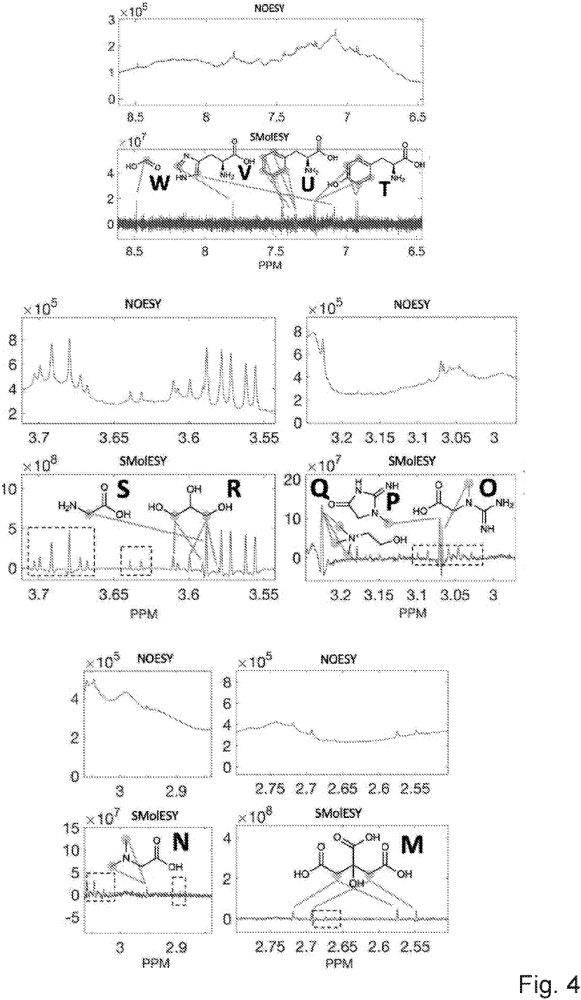

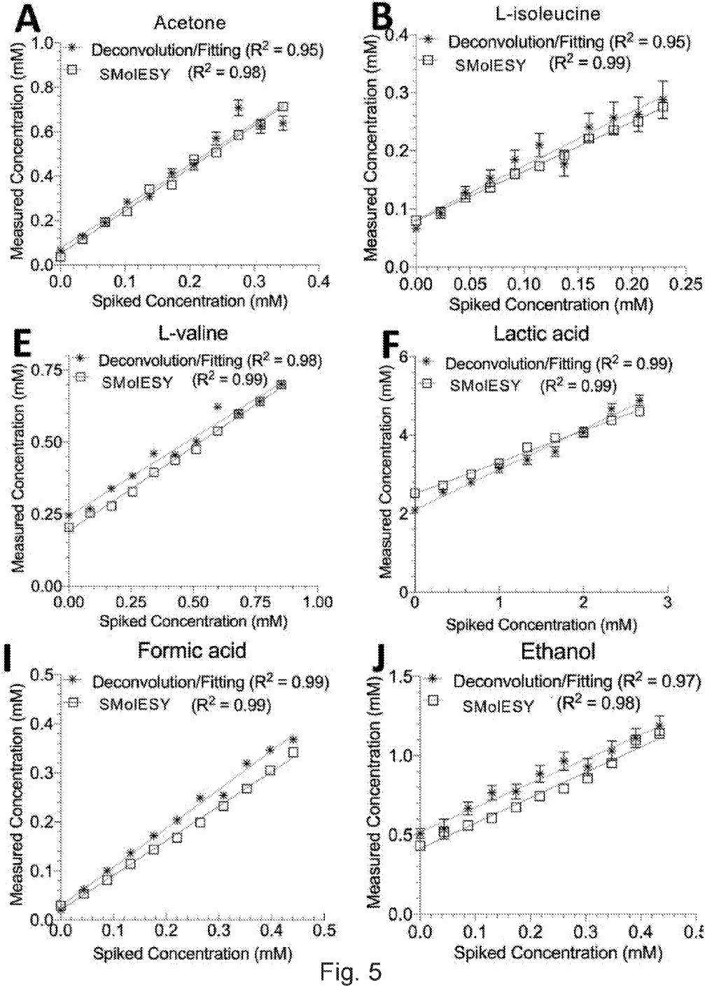

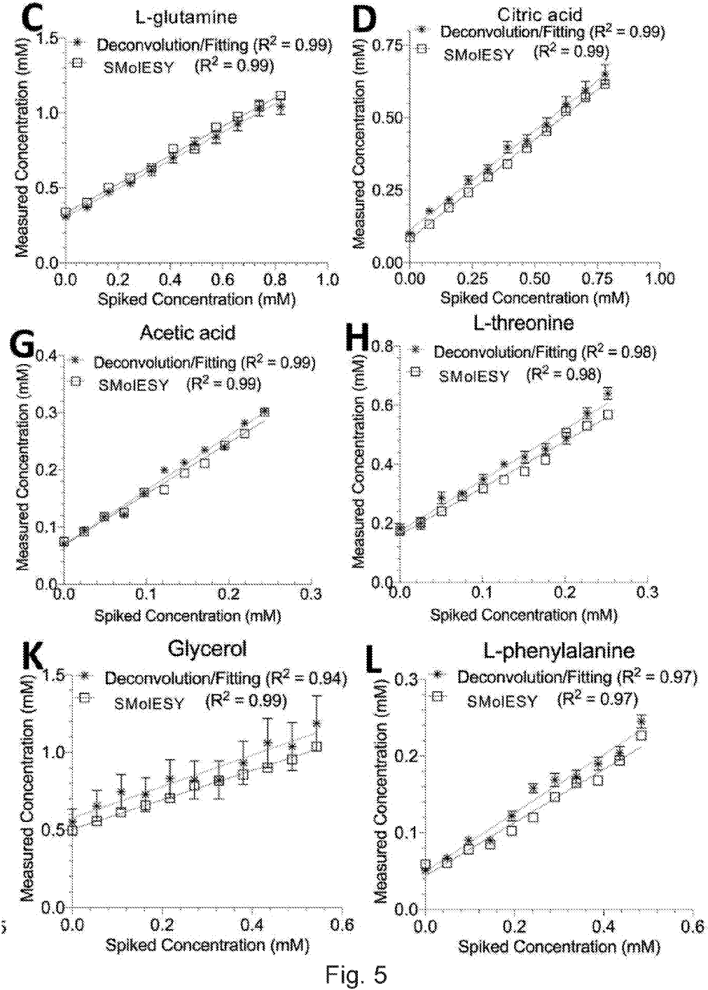

Comparison between spectral bins of SMolESY and CPMG spectral bins indicated a strong linear correlation for all spiked metabolites (R² > 0.98) (FIGS. 4A-C), even in cases where resonances overlapped with broad macromolecular signals (e.g. FIGS. 4B,C). Furthermore, the ease of quantification as well as immediate deconvolution of the SM signals by SMolESY is exemplified in a randomly selected plasma spectrum, where the immediate identification and integration of above 20 metabolites’ signals at high resolution and without interference from broad signals or baseline distortions (FIG. 4DW) is accomplished. The metabolite quantification by straightforward integration of SMolESY features (see paragraph SMolESY signals integration procedure in the Experimental section) was compared to outputs of standard 1D-NOESY peaks’ deconvolution and fitting algorithms (Bruker Biospin, www.bruker.com, commercially available IVDr quantitation and in-house algorithms). SMolESY-based quantification results for the tested spiked metabolites follow a linear correlation with spiked concentrations, as well as with the measured values from deconvolved/fitted 1D-NOESY data (FIG. 5).

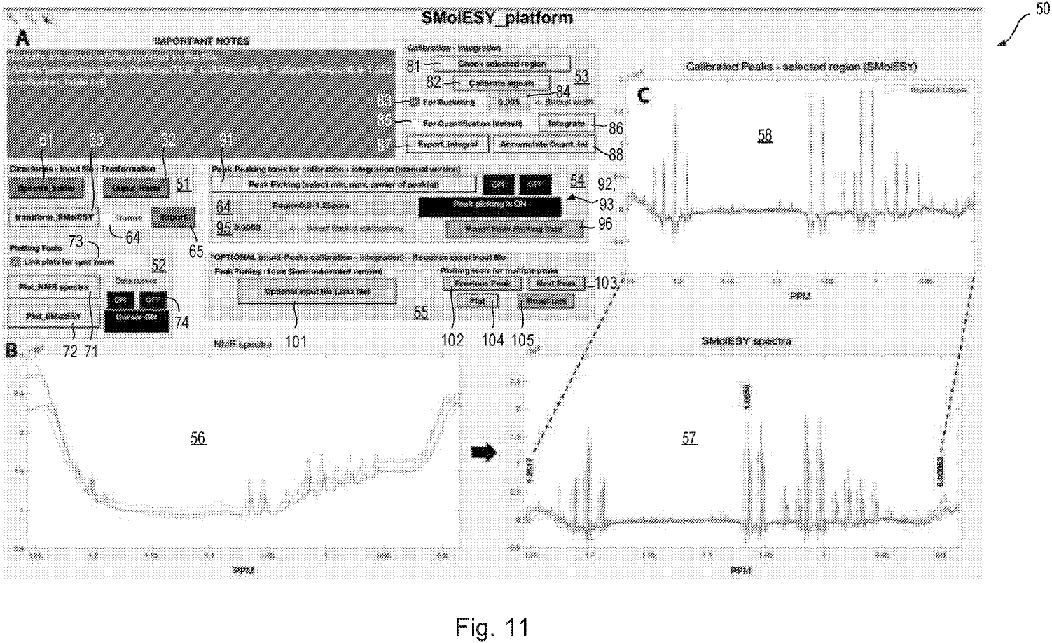

To facilitate the implementation of SMolESY in both targeted (direct metabolite signal integration), untargeted (profiling/fingerprinting) and quantitative NMR (qNMR) applications, a “SMolESY_platform” can be used for producing and processing SMolESY data from raw NMR spectra. SMolESY_platform is hereinafter described with reference to FIG. 11 and at https://github.com/pantakis/SMolESY_platform, which is incorporated herein by reference.

The compromising effect that common macromolecules (proteins, lipids and polysaccharides) exhibit on individual quantitative SM measurements and on the broader SM profile has yet to be adequately addressed. Consequently, modern standard protocols for biofluid, cell extracts, food and other rich in macromolecules complex mixtures analysis rely on a sequence of experiments, each of which is individually flawed in application to the most common of biofluids (e.g. blood products). Whereas 1D-NOESY cannot be used for MVA, CPMG cannot be used for accurate and reliable quantification. Here we demonstrate that the computational transformation of the standard ₁D ₁H-NMR experiment yields both high fidelity spectral SM profiles and data from which quantitative chemical measurements can be extracted.

Systematic evaluation of SMolESY clearly demonstrates its ability to cleanly suppress macromolecular signals in synthetic test cases (albumin titration), common agricultural products (milk and oil), and human plasma. In all cases, the suppression of macromolecular signals resulted in the enhancement of SM-derived information from the SMolESY’s ability to reproduce the SM-derived information captured by the 1D ¹H-NMR with high fidelity, ensuring the transformation is not detrimental to SM signals. SMolESY implementation both on a large cohort of more than 3000 individuals’ plasma samples and > 100 urine samples showed an outstanding reproducibility with virtually no loss of metabolic information. Although the approach does risk decreasing the s/n of very broad signals such as those from highly exchangeable and/or interacting protons of small molecules (e.g. urea), generally such signals are of low fidelity in ¹H-NMR analyses unless specific experiments or sample preparation procedures are employed. This risk can be further mitigated by applying smoothing algorithms such as traditional or advanced approaches for signal denoising on the SMolESY data acquired by our toolbox.

Additionally, our method helped to the recovery of some signals in crowded regions of the spectrum and areas where macromolecule signals appear. This, combined with the expected enhancement to spectral resolution when calculating signal derivatives, facilitates the chemical assignment of SMs by increasing the analytical specificity. Furthermore, the linear mathematical transformation preserves the quantitative aspects of the data, given the appropriate calibration and reference signal from reference compounds or electronically produced by the PULCON experiments. SMolESY can therefore be used directly for absolute quantification without the need for complex and computationally expensive deconvolution algorithms typically applied to 1D experiments and unlike spin-echo pulse sequence experiments altogether. Importantly, these improvements can also be realized post hoc by retrospective application of SMolESY to existing 1D ¹H-NMR raw spectra. This could be of major importance for NMR analysis of sample types with low physiological macromolecular content (e.g. urine) for which spin-echo experiments are not routinely acquired, yet which occasionally or in pathological Moreover, SMolESY is also readily applicable to historical datasets increasing its value and making them comparable with new processed datasets. Its application only requires high resolution ¹H-NMR data (> 65 k data points) input which is the established norm within modern high-quality metabolomics and analytical studies.

### Conclusions

SMolESY is well suited for the enhancement of small molecule profiles in NMR spectra derived from complex sample types exhibiting broad and confounding macromolecular signals. In its simplest form as a partial derivative, 1D ¹H-NMR spectra are transformed yielding effective suppression of macromolecular signals and enhanced clarity and resolution of small molecule signals. The quantitative capacity of the original data is preserved and, despite variable reductions in the s/n measured across the spectrum, the total chemical information recovered from SMolESY is greater than that from CPMG (demonstrated in human plasma and serum as major biological matrices of interest). Thus, the validation set presented herein and applications to various sample types establish SMolESY as a functional in silico replacement for the routine CPMG experiment (or other spin echo variants).

The approach may further enable higher throughput sample preparation procedures by precluding the removal of macromolecules from sample types where such preparation is routine practice (e.g. for the NMR study of various food matrices). SMolESY is therefore of major significance in biomedical research, food industry, environmental sciences and indeed any other applications where ¹H-NMR is applied to chemically complex samples with abundant macromolecules. The approach is particularly pertinent for large cohort studies where up to 30% acquisition time could be saved compared to the conventional NMR-metabolomics pipeline. Since ¹H-NMR is emerging as the dominant technique for large scale application to biofluid analysis (e.g. supporting molecular epidemiology and biobanking efforts) and increasingly used for routine quality control assessment of agricultural products, we believe the time and cost savings provided by SMolESY will support the future application of NMR in these contexts.

### Experimental

### Differentiation of Imaginary Spectral Data – Basic Theory

Herein, the numerical differentiation (first derivative) of spectral data was calculated by the “gradient” function integrated in MATLAB programming suite (MathWorks, version R2019b). In general, the first derivative of a signal is the rate of change of y (i.e. intensity data) with x (ppm data), dy/dx, which in practice is the slope of the tangent to the signal at each point across the ppm axis. It has been shown that the maximum intensity of a signal in the derivative spectrum is inversely proportional to its linewidth to the half-height (Δv_{½}), and therefore very broad signals are significantly suppressed while the Δv_{½} of sharp signals are further narrowed (see below). Importantly, and in contrast to differentiation of the real data, the 1^{st} derivative of the imaginary data yields positive peak intensities (> o baseline, see below) owing to the gradient of all signals described by the imaginary data. Derivative spectroscopy could enhance the resolution of a signal, whereas a broad signal could be completely attenuated, which could be easily described in the following equations.

Assuming a Fourier transformed Lorentzian signal f(x) across a specific frequency region equals to:

$$f \left(x\right) = \frac{{I}_{δ}}{1 + {\left(\left(x - δ\right) / Δ {v}_{1 / 2}\right)}^{2}}$$

where I_{δ} is the maximum intensity of the signal at a specific chemical shift (δ) and Δv_{½} is the linewidth at the half-height of the signal, the 1^{st} derivative of f(x) is:

$${f}^{′} \left(x\right) = \frac{- {I}_{δ} ( 2 x - 2 δ )}{Δ {v}_{1 / 2} {\left(\frac{{\left(x - δ\right)}^{2}}{Δ {v}_{1 / 2}} + 1\right)}^{2}}$$

From Eq.2, it can be seen that signals with large Δv_{½} (e.g. broad signals of macromolecules) are highly suppressed to zero (I_{δ} ~ o), whereas sharp signals (i.e. small Δv_{½} values) are extra sharpened, thus enhancing spectral resolution.

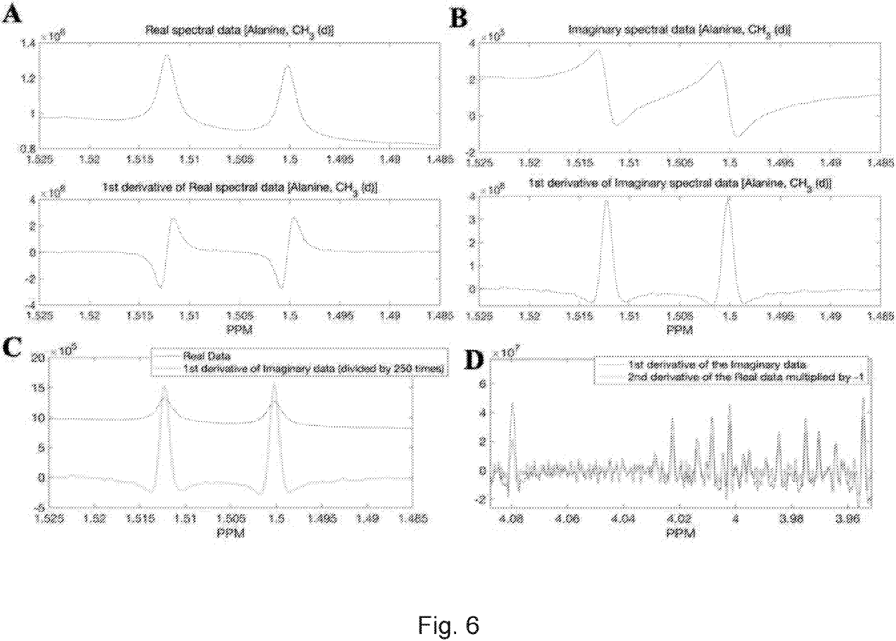

The 1^{st} numerical derivative of the real data from an NMR spectrum (after Fourier transform and phase correction), produces an antisymmetric signal (positive on one side and negative on the other) (FIG. 6A), whereas the 1^{st} derivative of the imaginary data, due to its gradient (namely positive-negative maxima per signal) (FIG. 6B), produces a positive transformed signal, which exhibits the same δ as the real data, without applying any symmetrisation algorithms. The transformed signal from the imaginary spectral data exhibits no chemical shifting compared to the real spectrum (FIG. 6C) and it could be immediately employed for any NMR-based metabolomics or analytical study. Furthermore, as differentiation is a linear technique the amplitude of any transformed signal is directly proportional to the original signal, therefore theoretically retaining its quantitative nature. The same signal (i.e. at the positive side of the baseline) could be produced by the 2^{nd} derivative of the real data of the NMR spectrum multiplied by -1 or the 2^{nd} power derivative, however, signal-to-noise ratio is decreased (FIG. 6D) compared to the 1^{st} derivative.

### Reagents

All reagents employed for the artificial mixtures of metabolites, spiking experiments and buffers composition were purchased from Sigma Aldrich.

### Software

All scripts for the correlation analyses were coded in the MATLAB programming suite (MathWorks, version R2019b). The linear regression analyses, statistical comparisons between slopes and intercepts (i.e. F-tests), as well as their plotting, were performed by Prism 8 (GraphPad Software, Inc, 2019). Multivariate statistics was performed using the MATLAB based PLS Toolbox (Eigenvector Research, Inc., Manson, WA, USA 98831, version 8.7.1 (2019) software available at http://www.eigenvector.com).

### Artificial Mixtures Preparation – Spiking Experiments

The albumin concentrations in the NMR samples were o, 7.5, 15.0, 37.5, 75.0, 150.0 and 225.0 mM. The selected metabolites and their concentration for the initial artificial mixture were: cytidine (1 mM), benzoic acid (1 mM), citric acid (0.25 mM), caprylic acid (1 mM), L-isoleucine (0.375 mM), creatinine (0.5 mM), L-glutamic acid (0.5 mM), L-glutamine (0.625 mM), hippuric acid (0.625 mM), L-phenylalanine (0.8 mM), and L-tryptophan (0.375 mM). Artificial mixtures of small MW metabolites contained 50% plasma buffer (see below the plasma buffer composition) and 50% of the aqueous mixture of metabolites in different concentrations. After the initial mixture, 8 sequential (and equal) dilutions were performed, resulting in 9 different samples. Among all the metabolites we depict (FIG. 1D) those that exhibit a high variety of signals complexity (i.e. spin systems multiplicity) so as to test their signals (i.e. integrals) reproducibility when applying SMolESY.

The spiked 17 metabolites in a real plasma sample along with their 11 different concentrations are summarized in Table I below.

Table I

| Metabolites | Concentration (mM) | | | | | | | | | | |
|---|---|---|---|---|---|---|---|---|---|---|---|
| Lactic acid | 0 | 0.333 | 0.666 | 0.999 | 1.332 | 1.665 | 1.998 | 2.331 | 2.664 | 2.997 | 3.330 |
| 2-hydroxybutric acid sodium salt | 0 | 0.016 | 0.032 | 0.048 | 0.063 | 0.079 | 0.095 | 0.111 | 0.127 | 0.143 | 0.159 |
| Acetone | 0 | 0.034 | 0.069 | 0.103 | 0.138 | 0.172 | 0.207 | 0.241 | 0.275 | 0.310 | 0.344 |
| Citric acid | 0 | 0.078 | 0.156 | 0.234 | 0.312 | 0.390 | 0.469 | 0.547 | 0.625 | 0.703 | 0.781 |
| D-glucose | 0 | 0.611 | 1.221 | 1.832 | 2.442 | 3.053 | 3.663 | 4.274 | 4.885 | 5.495 | 6.106 |
| Ethanol | 0 | 0.043 | 0.087 | 0.130 | 0.174 | 0.217 | 0.261 | 0.304 | 0.347 | 0.391 | 0.434 |
| Glycerol | 0 | 0.054 | 0.109 | 0.163 | 0.217 | 0.271 | 0.326 | 0.380 | 0.434 | 0.489 | 0.543 |
| L-aspartic acid | 0 | 0.038 | 0.075 | 0.113 | 0.150 | 0.188 | 0.225 | 0.263 | 0.300 | 0.338 | 0.376 |
| L-glutamine | 0 | 0.082 | 0.164 | 0.246 | 0.328 | 0.411 | 0.493 | 0.575 | 0.657 | 0.739 | 0.821 |
| L-histidine | 0 | 0.045 | 0.090 | 0.135 | 0.181 | 0.226 | 0.271 | 0.316 | 0.361 | 0.406 | 0.451 |
| L-isoleucine | 0 | 0.023 | 0.046 | 0.069 | 0.091 | 0.114 | 0.137 | 0.160 | 0.183 | 0.206 | 0.229 |
| L-phenylalanine | 0 | 0.049 | 0.097 | 0.145 | 0.194 | 0.242 | 0.291 | 0.339 | 0.387 | 0.436 | 0.484 |
| L-threonine | 0 | 0.025 | 0.050 | 0.076 | 0.101 | 0.126 | 0.151 | 0.176 | 0.201 | 0.227 | 0.252 |
| L-tryptophan | 0 | 0.073 | 0.147 | 0.220 | 0.294 | 0.367 | 0.441 | 0.514 | 0.588 | 0.661 | 0.735 |
| L-valine | 0 | 0.085 | 0.170 | 0.256 | 0.341 | 0.427 | 0.512 | 0.598 | 0.683 | 0.768 | 0.854 |
| Sodium acetate | 0 | 0.024 | 0.049 | 0.073 | 0.098 | 0.122 | 0.146 | 0.171 | 0.195 | 0.219 | 0.244 |
| Sodium formate | 0 | 0.044 | 0.088 | 0.132 | 0.176 | 0.221 | 0.265 | 0.309 | 0.353 | 0.397 | 0.441 |

Each concentration of each metabolite was spiked in a new plasma sample, so in total ~17 × 11 ≈ 187 samples were prepared and their corresponding NMR spectra were acquired.

### NMR Samples Preparation and Spectra Acquisition Details

The total number of plasma (> 3200) and urine (~ 100) NMR samples were prepared following the established standard operating procedures for metabolomics analyses. Namely, the plasma NMR samples consisted of 50% plasma buffer [75 mM Na₂HPO₄; 6.2 mM NaN₃; 4.6 mM sodium trimethylsilyl [2,2,3,3-d4]propionate (TMSP) in H2O with 20% (v/v) ²H2O; pH 7.4] and 50% of blood plasma and urine NMR samples consisted of 10 % urine buffer [1.5 M KH₂PO₄ dissolved in 99.9% ²H2O, pH 7.4, 2 mM NaN₃ and 5.8 mM 3-(trimethylsilyl) propionic acid-d4 (TSP)] and 90 % of urine. The cow milk sample was prepared following the same protocol used for blood products and additional centrifugation cycle was required in order to remove extra fat content. The olive oil sample was prepared by diluting the sample 10 % in deuterated chloroform.

Solution ¹H NMR spectra of all samples were acquired using a Bruker IVDr 600 MHz spectrometer (Bruker BioSpin) operating at 14.1 T and equipped with a 5 mm PATXI H/C/N with ²H-decoupling probe including a z-axis gradient coil, an automatic tuning-matching (ATM) and an automatic refrigerated sample changer (Sample-Jet). Temperature was regulated to 300 ± 0.1 K and 310 ± 0.1 K for urine and plasma samples, respectively. For each blood NMR sample, 3 NMR experiments were acquired in automation: a general profile ¹H NMR water presaturation experiment using a one-dimensional pulse sequence where the mixing time of the 1D-NOESY experiment is used to introduce a second presaturation time, a spin echo edited experiment using the Carr-Purcell-Meiboom-Gill (CPMG) pulse sequence which filters out signals from fast T₂ relaxing protons from molecules with slow rotational correlation times such as proteins and other macromolecules, and a 2D J-resolved experiment. Each experiment had a total acquisition time of approximately 4 minutes [32 scans were acquired for the 1DNOESY (98,304 data points, spectral width of 18,029 Hz) and the 1D-CPMG (73,728 data points, spectral width of 12,019 Hz) experiments while 2 scans and 40 planes were acquired for the 2D J-resolved experiment].

For each urine sample 2 NMR experiments were acquired as previously published in A. C. Dona et al., Anal. Chem., 2014, 86, 9887-9894 which is incorporated herein by reference. Free induction decays of all 1D-spectra were multiplied by an exponential function equivalent to 0.3 Hz line-broadening before applying Fourier transform. All Fourier transformed spectra were automatically corrected for phase and baseline distortions and referenced to the TSP singlet at 0 ppm.

### Plasma – Urine Spectra Employed for the Present Study

In the present study, we randomly selected ~3000 plasma ¹H-NMR spectra (both 1D-NOESY and CPMG) from the National Phenome Centre repository, previously acquired for various clinical and epidemiology phenotyping studies. Of these, approximately 1000 plasma spectra corresponded to plasma-EDTA samples, and the rest (~2000) to heparin plasma samples. Both heparin and EDTA collected plasma samples were selected for the SMolESY validation in order to highlight the broad applicability of this approach.

Urine ₁D-NOESY ₁H-NMR spectra were taken from a publicly available study (available at Metabolights, accession number: MTBLS694).

### Signal-to-Noise Ratio (s/n) and Peak Picking Calculations

Signal-to-noise ratios (s/n) of selected ¹H NMR signals from the CPMG and SMolESY NMR profiles, namely, from L-Alanine, Glucose, L-phenylalanine and formic acid were calculated as the ratio of peak intensity at maximum height to the standard deviation of the noise for each of the 3020 CPMG and SMolESY plasma spectra. Noise was calculated as indicated in A. Rodriguez-Martinez et al., Anal. Chem., 2017, 89, 11405-11412 which is incorporated herein by reference. The selected signals resonate at different spectral areas with variable amount of noise and exhibit different multiplicities. The whole number of “peak-picked” signals was calculated by using the “findpeaks” Matlab function, implementing as threshold the calculated level of noise for the CPMG and SMolESY spectra, respectively.

### Multivariate Analyses (MVA) Details

Principal component analysis (PCA) was performed for the ₁DNOESY and the SMolESY ₁H-NMR urine datasets, after excluding H₂O spectral region (4.7-4.84 ppm) for the spectral width 0.5-10 ppm. Both ₁D-NOESY and SMolESY ₁H-NMR spectra were calibrated to TSP signal (singlet) at 0 ppm. No binning was applied to the data, all data points for each spectrum were used as variables. For the PCA analysis, NMR data was mean centered and no normalization was applied so as to have intact signals contribution to the PCA analysis.

### “SMolESY_Platform” Toolbox Details

In order to facilitate the implementation of SMolESY data into NMR metabolomics analyses and NMR-based analytical deconvolution of complex matrices content, we created a graphical user interface toolbox (SMolESY_platform) for the SMolESY data generation, exportation as well as pre-treatment for any metabolomics pipeline. Our software enables the loading of the ordinary biofluids ₁D-NMR spectra and their transformation to SMolESY along with the visualization of both ₁H-NMR and SMolESY spectra for any comparison. Furthermore, it offers the opportunity for the calibration of SMolESY data to a reference peak (for example, to the anomeric doublet resonance of glucose at ~5.25 ppm for plasma/serum/cerebrospinal fluid/pancreatic juice). In addition, the SMolESY_platform provides: i) a semi-automated alignment and integration of SMolESY signals for absolute quantification (i.e. targeted approach) and ii) a variable shaped binning algorithm for untargeted metabolomics studies (i.e. diseases fingerprinting etc.). Both signals and bin-tables (i.e. bucket tables) integration values can be exported for further statistical. The SMolESY_platform is described in more detail with reference to FIG. 11 and at https://github.com/pantakis/SMolESY_platformwhich is incorporated herein by reference.

### SMolESYsignals Integration Procedure

To calculate the absolute concentration of each metabolite from the SMolESY spectra, we simply integrated the signals taking the transformed ERETIC signal (i.e. in our case it was the Quantref electronic signal generated by Bruker Biospin) as a reference.

### System

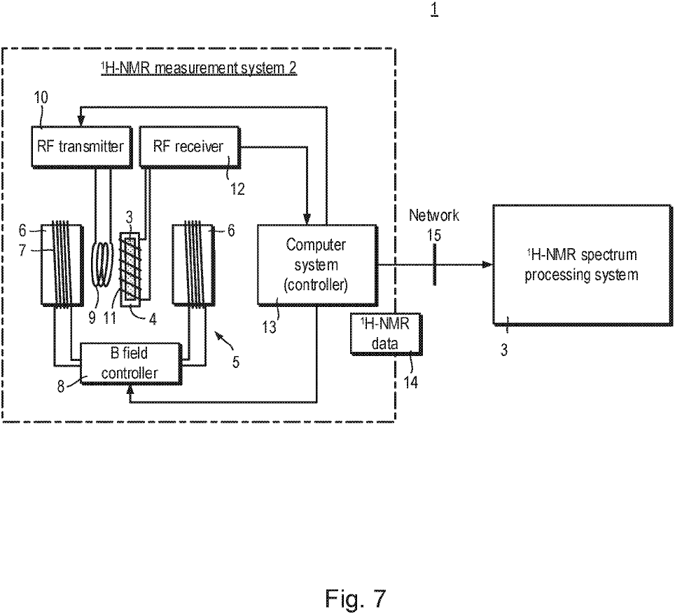

Referring to FIG. 7, an ₁H-NMR measurement and data processing system 1 is shown.

The system 1 includes an ₁H-NMR measurement system 2 and an ₁H-NMR data processing system 3.

The ₁H-NMR measurement system 2 can be used to perform ₁H-NMR spectroscopy on a sample 3 held in a sample holder 4.

The ₁H-NMR measurement system 2 includes a magnet field generator 5 which includes magnetic poles 6 and windings 7 which can be driven by a magnetic field controller 8. The sample 3 subjected to a magnetic field which can be swept. The ₁H-NMR measurement system 2 also includes a first coil 9 which can be driven by an rf transmitter 10 so as to subject the sample 3 to rf excitation and a second coil 11 wound around the sample holder 4 to detect an rf signal emitted by the sample ₃. The second coil 11 is connected to a receiver 12 which may include an amplifier (not shown) and an ADC (not shown) for decimating the received signal. A controller 13, typically in the form of a computer system, is used to control the magnet field controller 5 and rf transmitter 10, and to collect data from rf receiver 12. An example of a suitable ₁H-NMR measurement system 2 is the Bruker IVDr 600 MHz spectrometer (Bruker BioSpin).

The ₁H-NMR data processing system 3 can be used to process ₁H-NMR spectral data 14 generated by ₁H-NMR measurement system ₂. In this example, the ₁H-NMR measurement system 2 is connected to the ₁H-NMR data processing system 3 by a network 15 (for example, a LAN or the Internet). The systems ₂, ₃, however, need not be connected and data 14 may be transferred in other ways. For example, data may be transferred via removeable storage (not shown).

The ₁H-NMR data processing system 3 is a computer system, which may take the form of a workstation, desk-top computer, lap-top computer or other sufficiently powerful computing device.

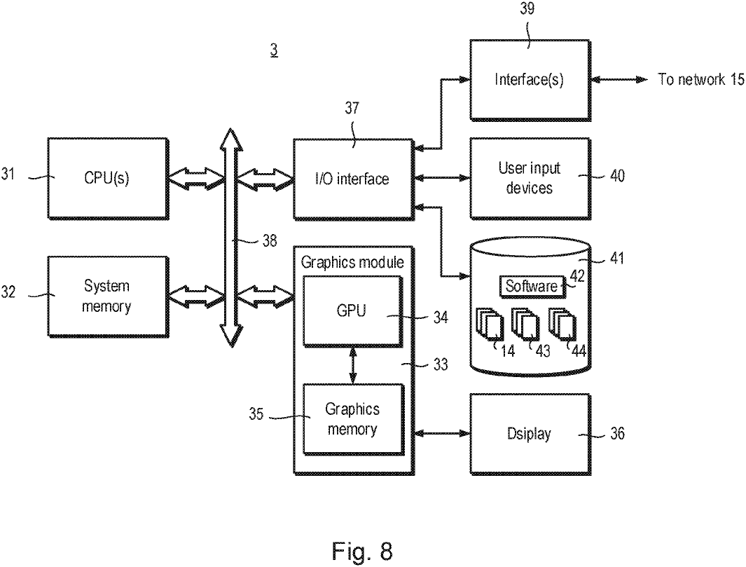

Referring also to FIG. 8, the ¹H-NMR data processing system 3 is shown in more detail.

The computer system 3 includes one or more central processing units (CPUs) 31 having respective memory caches (not shown), system memory 32, a graphics module 33 in the form of a graphics card, which includes a graphics processing unit (GPU) 34 and graphics memory 35 (which may be referred to as “video RAM”), connected to one or more displays 36, and an input/output (I/O) interface 37 operatively connected by a bus system 38.

The I/O interface 37 is operatively connected to bus and/or network interface(s) 39 (such as Ethernet interface or WLAN interface) for receiving the ₁H-NMR spectral data 14. The I/O interface 37 can also be connected to and control the ₁H-NMR measurement system 2.

The I/O interface 37 is also operatively connected to user input devices 40 (such, as a keyboard, mouse and/or touch screen) and the storage 41, for example, in the form of one or more hard disk drives and/or solid-state drives. Some peripheral devices, such as removable storage, and other computer components are not shown. The computer system 3 may have a different configuration from that shown in FIG. 8.

Storage 41 also holds computer software 42 for processing ₁H-NMR spectral data 14 using the method herein described and for storing Fourier transform data 43 and SMolESY spectra 44 (herein also referred to as the “first derivative”).

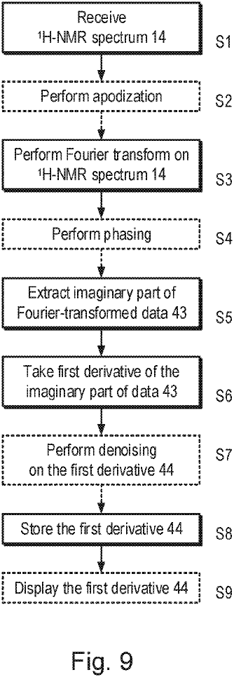

Referring also to FIG. 9, the processor(s) 31 retrieves a free induction decay data set, i.e. ₁H-NMR spectral data 14, from storage 41 (step S1).

Optionally, the processor(s) 31 may perform apodization (or “windowing”) by applying an apodization (step S₂). For example, the apodization function may be an exponential multiplication, Gaussian multiplication or other suitable function for enhancing signal-to-noise ratio. Apodization may be selected by a user.

The processor(s) 31 performs a Fourier transform of the (apodized) ₁H-NMR spectral data 14 to obtain Fourier-transformed spectral data 43 (step S₃). The Fourier-transformed spectral data 43 includes real and imaginary parts.

Optionally, the processor(s) 31 may perform phase correction (step S₄). This may, for example, involve multiplying the real part of the Fourier-transformed spectral data 43 by a sine function and the imaginary part of the Fourier-transformed spectral data by a cosine function. Phase correction may be selected by the user.

The processor(s) 31 extracts the imaginary part of the Fourier-transformed spectral data 43 (step S6) and performs first differentiation of the data 43 to obtain a first derivative 44 (or “SMolESY spectrum”) (step S6).

Optionally, the processor(s) 31 may perform de-noising of the first derivative 44.

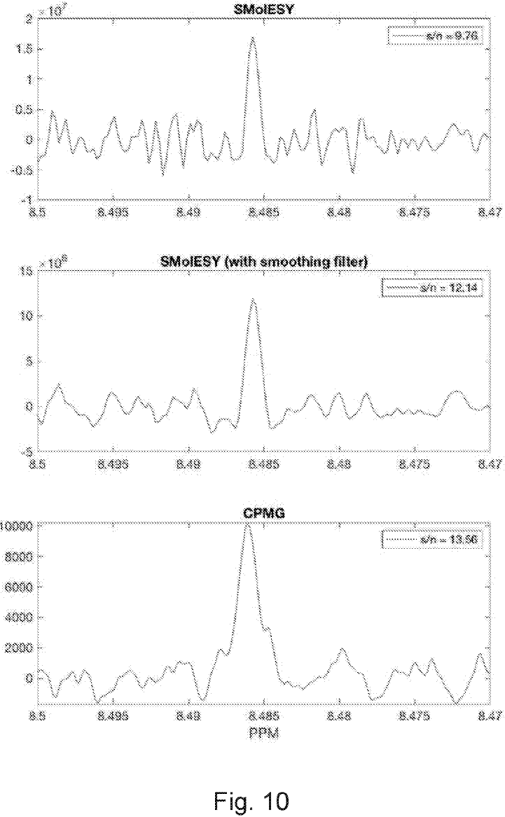

Referring to also to FIG. 10, de-noising the first derivative 44 may comprise applying a low-pass filter. The low-pass filter may have coefficients equal to the reciprocal of window span, i.e., the span of the first derivative.

Other forms of denoising can be used such as applying local regression or applying a Savitzky-Golay filter. Applying the local regression may comprise applying local regression using weighted linear least squares and a first-degree polynomial model and/or applying local regression using weighted linear least squares and a second-degree polynomial model. Applying a Savitzky-Golay filter generally involves a moving average with filter coefficients determined by an unweighted linear least-squares regression and a polynomial model of specified degree.

De-noising may be selected by the user.

The SMolESY data 44 (i.e., the (de-noised) first derivative 44) is then stored in storage 41 (step S8). The SMolESY data 44 (can optionally be displayed (step S9). Additionally, or alternatively, the SMolESY data 44 can be transmitted to a remote location via the network interface 39.

Referring to FIG. 11, a user interface 50 (the “SMolESY_platform graphical user interface”) for controlling processing and display of spectral data is shown.

The user interface 50 includes first, second, third, fourth and fifth input regions 51, 52, 53, 53, 54, 55 for receiving user input and first, second and third output (or “display”) regions 56, 57, 58 for display spectra or portions of spectra.

The first input region 51 (“Directories - Input file - Transformation” region) includes buttons 61, 62 for selecting folders for importing and exporting data, a button 63 for instructing the performing a transformation of free induction decay data set into SMolESY spectrum, a check box 64 for selecting glucose and a button 65 for instructing the system 3 to export SMolESY data.

The second input region 52 (“Plotting Tools”) includes buttons 71, 72 for instructing the system 3 to plot NMR spectra and SMolESY, a check box 73 for selecting linking plots and data cursor controls 74.

The third input region 53 (“Calibration - Integration” region) includes buttons 81, 82 for instructing the system 3 to check selected region and to calibrate signals, a check box 83 for selecting data for bucketing, a field 84 for providing a bucket size, a check box 85 for selecting quantification, a button 86 for instructing the for instructing the system 3 to integrate, buttons 87, 88 for instructing the system to export the integral and to accumulate quantitive integral.

The fourth input region 54 (“peak Peaking tools for calibration - integration (manual version” region) includes a button 91 to instruct the system to peak pick, buttons 92, 93 for instructing the system (and showing whether) peak picking is on or off, input fields 94, 95, a button 96 for instructing the system to reset peak picking data.

The fifth input region 55 (“OPTION (multi-Peaks calibration - Integration) (manual version” region) button 101 for selecting folders for importing an input file and buttons 102, 103 for instructing the system 3 to select previous and next peaks, a button 104 for instructing the system to plot and a button 105 for instructing the system to reset the plot.

The first display region 56 can be used to display the NMR spectra.

The second display region 57 can be used to display the SMolESY spectra.

The third display region 58 can be used to display calibrated peaks from the SMolESY spectra.

### Modifications

It will be appreciated that various modifications may be made to the embodiments hereinbefore described. Such modifications may involve equivalent and other features which are already known in the design, manufacture and use of NMR systems and component parts thereof and which may be used instead of or in addition to features already described herein. Features of one embodiment may be replaced or supplemented by features of another embodiment.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A computer-implemented method, comprising:
receiving ¹H-NMR spectral data for a sample;
performing a Fourier transform of the ¹H-NMR spectral data to obtain Fourier-transformed spectral data;
first differentiating the imaginary part of the Fourier-transformed spectral data or processed Fourier-transformed spectral data obtained from the Fourier-transformed spectral data to obtain a first derivative; and
storing the first derivative in storage.

2. The method of claim 1, wherein performing the Fourier transform comprises:
performing a one-dimensional Fourier transform of the ¹H-NMR spectral data.

3. The method of claim 1, wherein performing the Fourier transform comprises:
performing a numerical Fourier transform of the ¹H-NMR spectral data.

4. The method of claim 1, wherein the ¹H-NMR spectral data consists of at least 65,000 datapoints.

5. The method of claim 1, further comprising:
apodizing the ¹H-NMR spectral data prior to performing the Fourier transform using an apodization function.

6. The method of claim 1, further comprising:
processing the Fourier-transformed spectral data to generate processed Fourier-transformed spectral data.

7. The method of claim 6, wherein the processing the Fourier-transformed spectral data comprises:
performing phase correction on the Fourier-transformed spectral data.

8. The method of claim 1, further comprising:
denoising the first derivative.

9. The method of claim 8, wherein the denoising the first derivative comprises:
applying a low-pass filter.

10. The method of claim 8, wherein the denoising the first derivative comprises:
applying local regression.

11. The method of claim 8, wherein the denoising the first derivative comprises:
applying a Savitzky-Golay filter.

12. A computer program product comprising a non-transitory computer readable medium storing the first derivative obtained by the method of claim 1.

13. A computer program product comprising a non-transitory computer readable medium storing or carrying a computer program which comprises instructions which, when executed by at least one processor, causes the at least one processor to perform the method of claim 1.

14. Apparatus comprising:
at least one processor; and
memory;
wherein the at least one processor is configured:
to receive ¹H-NMR spectral data for a sample;
to perform a Fourier transform of the ¹H-NMR spectral data to obtain Fourier-transformed spectral data;
to first differentiate the imaginary part of the Fourier-transformed spectral data or of processed Fourier-transformed spectral data obtained from the Fourier-transformed spectral data to obtain a first derivative; and
to store the first derivative in memory or storage.

15. A system, comprising:
storage storing one or more sets of ¹H-NMR spectral data;
apparatus for processing ¹H-NMR spectral data, the apparatus configured to retrieve the one or more sets of ¹H-NMR spectral data from storage and to perform the method of claim 1 on each respective set of ¹H-NMR spectral data.

16. A system, comprising:
¹H-NMR measurement system for generating ¹H-NMR spectral data for a sample; and
apparatus for processing ¹H-NMR the spectral data, the apparatus configured to perform the method of claim 1 using ¹H-NMR spectral data from the ¹H-NMR measurement system.
